(19) United States
(12) Patent Application Publication
(10) Pub. No.: US 2013/0271210 A1
(43) Pub. Date: Oct. 17, 2013

(54) N-PATH FILTER WITH COUPLING BETWEEN PATHS

(71) Applicant: Thomas Riley, Osgoode (CA)

(72) Inventor: Thomas Riley, Osgoode (CA)

(73) Assignee: KABEN WIRELESS SILICON INC., Osgoode, ON (CA)

(21) Appl. No.: 13/996,572

(22) PCT Filed: Dec. 23, 2011
(86) PCT No.: PCT/CA2011/050806

§ 371 Date: Jun. 21, 2013

Related U.S. Application Data
(60) Provisional application No. 61/426,644, filed on Dec. 23, 2010.

(51) Int. Cl. H03H 11/04; H03H 7/01

(52) U.S. Cl. CPC H03H 11/04; H03H 7/0138
USPC 327/554; 333/132; 333/101

(57) ABSTRACT

An N-path filter with each path forming a different filter. A signal insertion block is provided at the start of the circuit and, in one embodiment, multiple memory capacitors are coupled to the signal insertion block. A bank of sequential rotating capacitors are provided along with a bank of switches. By activating selected switches, any of the memory capacitors can be coupled to selected rotating capacitors. A different filter subcircuit is formed by coupling each memory capacitor to different rotating capacitors as this creates a different signal path. By timing the switching of the rotating capacitors, signals from previous outputs can be inserted into the circuit. At the output end of the circuit, the output of the different filter subcircuits is put together into an output for the whole circuit.

### TECHNICAL FIELD

The present invention relates to electrical circuits. More specifically, the present invention relates to an N-Path filter circuit in which each path filter through the circuit forms a substantially identical filter.

### BACKGROUND OF THE INVENTION

Sampled analog filters are described mathematically the same way as digital filters; the difference is that the time-sampled signal is represented as a an analog signal such as a charge or a voltage in switched capacitor circuits or as a current in switched current or charge-domain filters whereas in a digital filter the time-sampled signal is represented as a quantized number.

A conventional sampled analog filter can be single ended, having one path. In the conventional analog filter, a charge is collected on a capacitor forming a first part of the filter circuit through an input switch, and is then transferred to other capacitors forming other parts of the filter circuit through other switches and operational amplifiers (opamps). At the input of the sampled analog filter is a signal inserter, which converts an input signal into a charge stored on the first capacitor. Many ways to do this are known to those skilled in the art. Examples include, but are not limited to, i) sampling the voltage of an input signal by opening a switch which connects the input to the first capacitor, or ii) integrating a current proportional to an input signal onto the first capacitor for a predetermined amount of time. In a switched current filter, the inserter would typically involve switching an input current to one of N current copiers. In a digital circuit, the signal inserter would consist of applying an input bus to registers clocked on N phases at the same clock frequency. In a charge domain filter, the inserter would apply time-varying, weighted currents with N phases to N charge accumulators at the same clock frequency.

The conventional sampled analog filter can be differential as well as single ended. Here, two identical signal paths having simultaneous differential (180 degrees out of phase) signals are sampled simultaneously.

Further, conventional sampled analog filters can be complex, in which two parallel (possibly differential) signals, representing simultaneous quadrature components of a complex signal, are filtered. Here, charges, which represent the real and imaginary parts of the complex signal, are transferred from capacitor to capacitor in each parallel path of the filter, as well as between the parallel paths. The sampling times are simultaneous for all capacitors in both paths.

As an extension to a complex filter, polyphase filters can be realized, in which N parallel phases each carry a signal representing a 360/N degree phase of the complex signal being filtered. While polyphase filters may not provide any filtering capability over that of a complex filter, they do provide reduced sensitivity to component variations.

Conventional sampled analog filtering with a pass band B centered at f_{c} has an image pass band centered at fₛ+/−f_{c}. Achieving a high-Q filter with a high fₛ has been found difficult in the past. One approach to address the issue has been an N-path filter.

N-path filters differ from conventional sampled analog filters in that N paths identically filter the same real (or complex) signal, but at interleaved sampling times. As a result, a high sampling rate, fₛ can be achieved while each filter is actually sampled at a low sampling rate, fₛ/N. This eases the bandwith requirements for the components in each of the paths. In N-Path filters, a signal inserter and an output block are needed to convert one input signal to N interleaved signals and to convert the N interleaved, filtered signals to a output signal. Each path filter provides a filtered interleaved signal to the output block.

For conventional N-Path filters to work properly, the input block typically provides clocks to synchronize the generation of the interleaved signals and the output block has to be synchronized with the input block while taking into account any throughput delays in the path filters. Many approaches to address these synchronization issues are known to those versed in the art.

In this conventional N-path filter approach, each path of the N-path is a filter whose output and internal states are a function of its own inputs and previous outputs and internal states. Internal states of the filter arise from memory elements such as charge or voltage stored on capacitors that are not available at the input or output of the filter. As a result, using conventional sampled analog techniques, arbitrary transfer functions can be designed in the z domain. The z domain for each path is, however, constrained to operate at fₛ/N. This has the advantage that each path is clocked at a lower rate fₛ/N but requires a high clock rate fₛ to stream the input samples one at a time to each path and then re-assemble a common output by interleaving the outputs from each path when each path is the valid output. N-Path filters have an inherent advantage compared to other filters in that they are inherently less sensitive to errors in filter coefficients. This advantage applies to both the resolution of digital coefficients and the accuracy of analog coefficients in the form of capacitor or resistor ratios.

The above constraint that each path is clocked at fₛ/N results in a major difficulty of the N-Path filter that, for a given sampling rate fₛ, copies of the desired filter pass-band exist at frequencies corresponding to all multiples of fₛ/N.

The multiple pass bands can be inconvenient if blocking signals could occur at these frequencies. This can be partially compensated for by, as an example, using a low-Q continuous time filter which can preselect a desired band where a high-Q, N-Path filter does the final filtering.

For example, in a 3-Path filter, each path is a function of its own inputs and outputs which constrain the overall transfer function of the N-Path filter or its internal states to:

$$\frac{N ( {z}^{0} , {z}^{- 3} , {z}^{- 6} … )}{D ( {z}^{0} , {z}^{- 3} , {z}^{- 6} … )}$$

where N and D are some polynomials describing the poles and zeros of the overall N-Path filter.

Another problem that may be encountered is that the clocks for the filter, as well as dc offsets, mismatches, and other impairments, tend to create spurious tones at multiples of fₛ/N. However, the problem of clock feed-through, centered at the desired frequency-multiple of fₛ/N cannot be removed unless a notch is inserted in the pass-band, which will affect the desired signal if the signal has desired information spectrally close to fₛ/N. The issue of clock feed-through would be greatly lessened if the multiple copies of the desired filter pass-band at the fₛ/N frequencies could be shifted in frequency away from the spurious tones. While the clock feed-through would still exist at fₛ/N, the feed-through would no longer be in the filter pass-band. As a result it is desirable to have a N-path filter that shifts its pass bands away from the multiples of fₛ/N.

### SUMMARY OF INVENTION

The present invention provides an N-path filter with each path filter comprising a substantially identical filter. A signal insertion block is provided at the start of the circuit to make each path filter sequentially responsive to the input of the N-Path filter. Each path filter of the N-path provides a filtered output. An output block provides an overall output sequentially responsive to each of the path filters. The invention is characterised in that the output of each path filter is a function of its own input combined with at least one other input, the other inputs provided by a signal transfer mechanism coupled to at least one of the other path filters. This provides the advantage that the filter can be designed to shift poles and zeros to different frequency offsets from fₛ/N.

According to one aspect of the invention, each path filter is a digital filter. Digital filters are advantageous for many reasons. However, these advantages can be practically exploited only when an A/D converter of sufficient bandwidth and resolution is available for both the desired and undesired signals or when the signal is already available in digital form.

According to another aspect of the invention, each path filter is a discrete-time analog filter. The use of analog filters is often necessary to filter signals before A/D conversion or when a digital signal is not desirable.

According to another aspect of the invention, each path filter is comprised of at least one memory capacitor with charge periodically transferred from at least one other path using at least one rotating capacitor to perform the cross coupling between paths. This implementation has the advantage that it can be built with a minimum number of components and can be implemented with passive switched capacitor filtering.

According to another aspect of the invention, a rotating capacitor can also provide the output functionality. This has the advantage of reducing the number of components required to implement the output block.

According to a further aspect of the invention, the present invention provides a multiple path filter for filtering electronic signals, the filter comprising:

a signal insertion block, said signal insertion block receiving an input signal and converting said signal into a plurality of interleaved signals;
a plurality of path filters, each path filter receiving one of said interleaved signals and having a path filter output signal;
a cross-coupling mechanism, said cross-coupling mechanism, when activated, couples at least one of said path filters with at least one other path filter;
an output block, said output block receiving a plurality of path filter output signals from said path filters in an interleaved manner, said output block converting said path filter output signals into an output signal of said multiple path filter;
wherein
for each of said path filters, said path filter output signal is responsive to at least one signal from at least one other path filter received by way of said cross-coupling mechanism.

### BRIEF DESCRIPTION OF THE DRAWINGS

The embodiments of the present invention will now be described by reference to the following figures, in which identical reference numerals in different figures indicate identical elements and in which:

FIG. 1 is a block diagram of a typical 5-Path filter circuit;

FIG. 2 is a block diagram of an 3-Path filter according to one aspect of the invention;

FIG. 3 is a circuit diagram of a 3-Path filter according to the prior art;

FIG. 4 is a frequency response of a 3-Path filter according to the prior art and a frequency response of a 3-Path filter according to one aspect of the invention;

FIG. 5 is a circuit diagram of an N-path filter according to one aspect of the invention;

FIG. 6 is an illustration of the displacement of the pole locations on the unit circle when the invention is utilized; and

FIG. 7 illustrates a variant of a subcircuit of FIG. 5.

### DETAILED DESCRIPTION OF THE INVENTION

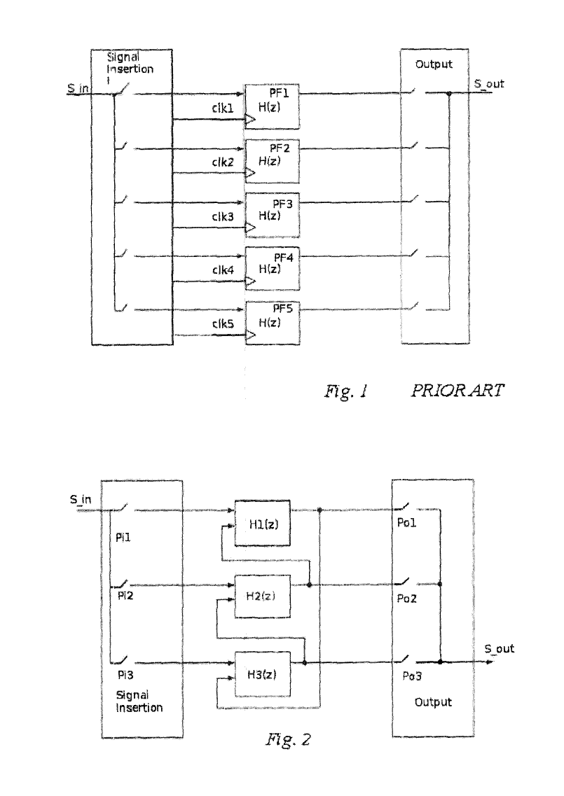

As can be seen from FIG. 1, an N-path filter according to the prior art has, at the leftmost portion of the circuit, a signal insertion block which periodically inserts signal into each path in the properly interleaved sequential order. Many of these signal insertion blocks are described in the N-path literature and known to those versed in the art. For this circuit, the filter produces an output out from an input in every 10 ns (corresponding to an fₛ of 100 MHz). Each of the path filters PF1 to PF5 is clocked at 20 MHz with clock phases which make the path filters sequentially responsive to a signal S_in. The signal insertion block provides clock phases, clk1 to clk5 such that clk2 is delayed from clk1 by 10 ns. Similarly each of clocks clk3 to clk4 is delayed by 10 ns relative to the previous clock for a total delay of 40 ns for clk4. As a result, clk1 is also delayed by 10 ns from its previous clock clk4. As part of the signal insertion block, clock generators generate control signals to support the signal insertion and the output transfer for each path filter. Generally, these clocks are not shown in subsequent diagrams.

For analog discrete time circuits clk1 to clk5, these would typically each be non-overlapping two-phase clocks and the switches shown in the signal insertion block would use transmission gates as shown, each closed for an appropriate amount of time to work with the path filters.

For digital discrete time circuits or some analog discrete time circuits, the switches in the signal insertion block would ensure that the inputs to each path filter are sampled on a clock edge of the clock for each path filter.

At the rightmost portion of the N-path filter in FIG. 1 is an output block to transfer a valid filtered interleaved signal to outputs to the overall output in the properly interleaved order. Examples of such output blocks are well-known in the art. In one embodiment, the output block samples interleaved voltages (from the path filters) to produce an overall output voltage. For a digital implementation of a path filter, the output block would be sampling interleaved digital numbers to produce an overall output digital number.

For analog discrete time circuits, the switches shown in the output block could each be enabled for 10 ns connecting each path filter output in sequence to the overall output out. Those versed in the art should know that the path filter output should be settled (i.e. valid) during the time it is applied to out. Alternatively, the outputs could be held for only 4.5 of the 10 ns available and sampled by a subsequent device.

For digital circuits, each path filter could drive an output bus for 10 ns. Similar to the analog case, only one path filter can drive the output at a time and each path filter must drive the output while its output is valid.

FIG. 2 describes one embodiment of the invention. In FIG. 2, the insertion block provides three clock phases Pi1, Pi2 and Pi3. These are used to control when each of three path filters PF1, PF2 and PF3 are responsive to an input signal S_in. H1(z) is responsive to S_in first at a time determined by Pi1. Subsequently, H2(z) is responsive to S_in at a time determined by Pi2. Subsequently, H3(z) is responsive to S_in at a time determined by Pi3. This repeats with Pi1 subsequent to Pi3. Each phase is delayed from the previous by a predetermined delay Ti.

In FIG. 2, each of the path filters implements a transfer function (Eqn 1):

out(z)=0.5out(z)z⁻³−0.5b(z)+a(z) (1)

This function requires that the output is generated from the previous output and the two inputs. Since the b input to each path filter is the output from two cycles previously on one of the other paths (Eqn 2):

out(z)=0.5out(z)z⁻³−out(z)z⁻²+a(z) (2)

This gives a transfer function on each path of (Eqn 3):

H(z)=out(z)/a(z)=1/(1+0.5z⁻²−0.5z⁻³) (3)

Many techniques to implement the transfer function of equation 1 with both analog and digital components are well known. To teach the full generality of the single invention, examples of both analog and digital techniques are discussed.

In FIG. 2, a digital embodiment according to the invention is comprised of digital components. The insertion block comprises three clock phases each with a 33% duty cycle. Each path filter comprises a rising-edge-triggered register, a three-input adder and a negator. The negator provides a negated b input which is the b input multiplied by −1. The register receives the output of the adder on its data input and one of the three clock phases on its clock input. The inputs to the adder are S_in, the output of the register and the negated b input. Both the negated b input and the output of the register are shifted by one bit when applied to the adder input to provide the factor of 0.5 in the transfer function. The output of each path filter is provided by the register output. The output block is a 3 input MUX with the MUX output selected by one of the three clock phases. The rising edge of Pi1 clocks the first path filter. Pi1 being high selects the first path filter as the MUX output. The other two paths operate in a corresponding fashion. The MUX output provides S_out.

For such a digital implementation, it should be noted that one switch would be required for each bit in the output word of the path filter. Clearly, for a digital implementation, the path filter output is implemented as a data bus and not as a single wire. The control logic for a digital implementation would be the same as that for an analog implementation.

In this example digital case, the transfer mechanism or cross-coupling mechanism comprises buses coupling the output of each path filter to the input of another path filter. The first path filter is responsive to the output of the second path filter. The other two path filters are responsive to a corresponding previous path filter output.

In FIG. 2, an analog embodiment of the invention is comprised of analog components.

Either the digital or analog path filters just described can be generically described as a multiple input discrete-time integrator. In this case, there are two inputs to the path filter, one of which is negated. In general there can be more inputs with arbitrary positive or negatively weighted inputs. Higher order filters can be implemented with a plurality of multiple input discrete-time integrators in each path filter.

In FIG. 3, the N-path filter operates by the selective activation and deactivation (opening and closing) of the switches in the circuit. By selectively opening and closing the switches, different signal paths are created to each of the path filters from a signal voltage source which is part of the signal insertion block for this filter.

Each of the N path filters in this case is a discrete time function of its own inputs and outputs.

For example, in a 3-path filter, if each path had access to the input signal, the output signal, or some intermediate signal from another path filter whose output was valid 2 cycles before the path filter output was valid, it would then be possible to create transfer functions of the form:

$$\frac{N ( {z}^{0} , {z}^{- 2} , {z}^{- 3} , {z}^{- 5} , {z}^{- 6} … )}{D ( {z}^{0} , {z}^{- 2} , {z}^{- 3} , {z}^{- 5} , {z}^{- 6} … )}$$

by using conventional sampled analog techniques. This removes the constraint imposed by conventional N-path filters that the transfer function of each path at base-band is replicated exactly at each multiple of fₛ/N.

Following on the above, in the 3-path case, taking a signal from the path which was the valid output 2 cycles ago from the current cycle is more advantageous than taking it from the path which was the valid output 1 cycle ago because it has more time to settle. In general, for an N-path filter, the most advantageous path to use is the path that completed N-1 cycles previously. For large values of N, this approach gives the cross-coupled path almost as much settling time as the original paths of the N-path filter.

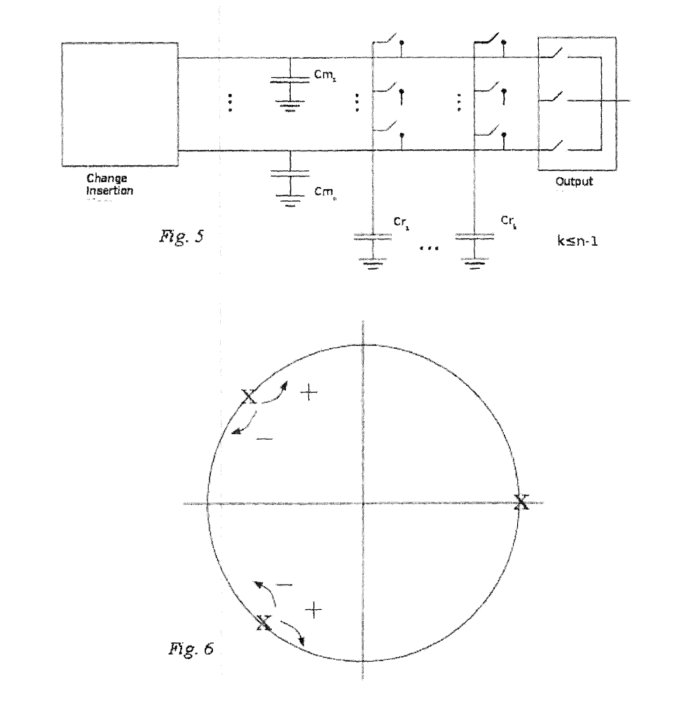

Although many techniques for transferring a signal one path to another are known, and many filter types are known, it is desirable to have a passive means of cross coupling between the paths. One such cross-coupling mechanism, a mechanism for allowing cross-coupling between path filters or for sharing charge between different path filters, is to add a bank of “rotating” capacitors to one or more of the filter sections, as shown in FIG. 5. Here, Cmₙ are the memory capacitors of a section of an N-path filter, and Crₖ are the rotating capacitors. The number of “rotating” capacitors k can be equal to, or less than the number of parallel paths n. As can be seen from the figure, the rotating capacitors can be coupled and uncoupled to any of the various path filters by simply closing and opening the various switches. Of course, for this implementation, the signal insertion block would be inserting a charge into the first memory capacitor of each of the parallel path filters. The first rotating capacitor for each path filter would thus transfer charge between the different paths by sharing its charge, in turn, with the first memory capacitor of each path filter. The rotating capacitor therefore couples to one path filter, samples the charge for that path filter, then uncouples from this first path filter and couples to another path filter, thereby sharing the charge of the first path filter with the second path filter.

The rotating capacitors are sequentially connected in parallel to each of the switched capacitors of the section of the N-path filter. In this manner, charge from each parallel signal path is “shared” with the other signal paths. Since the time interval between switching for each switched capacitor Cmₙ is N/fₛ, the time interval that a “rotating” capacitor is connected with a specific switched capacitor must be less than N/fₛ (in order to be shared between two or more switched capacitors without any idle time interval). For example, in a 3-Path filter in which each path has a time-staggered sampling interval of Y seconds (with the sampling of path 1 leading that of path 2 by Y/3 seconds, and the sampling of path 2 leading that of path 3 by another Y/3 seconds), a “rotating” capacitor could be connected to Path-1 for 2/3 Y seconds, to Path-3 for 2/3 Y seconds, and then to Path-2 for 2/3 Y seconds.

The transfer function of an N-path filter can be described mathematically in the Z domain as:

H(z)=1/[1±αz⁻ⁿ]

The sharing of charge between the parallel paths of an N-path filter can be described mathematically as:

H(z)=1/[1±α₁z⁻¹±α₂z⁻²±α₃z⁻³ . . . ±αₙz⁻ⁿ]

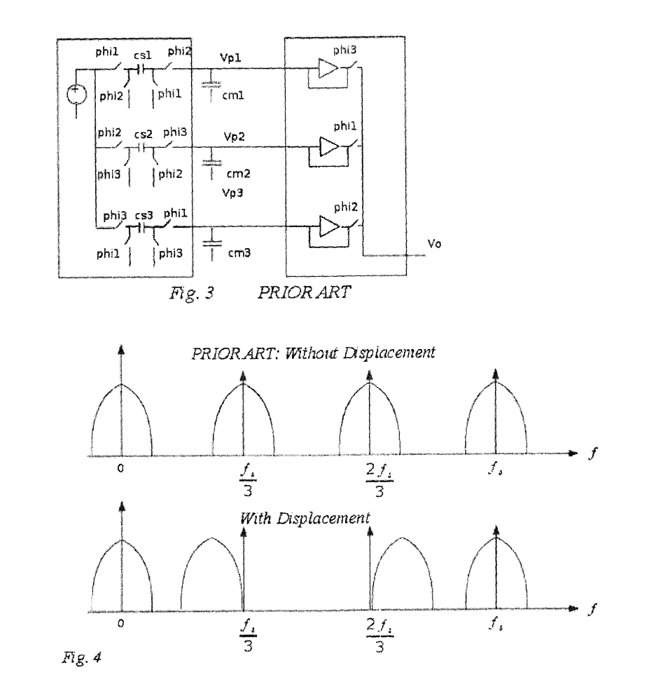

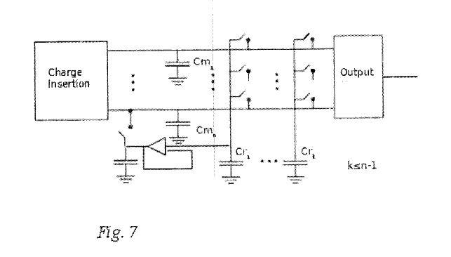

The effect of the more advanced transfer function is to move the pole locations on the unit circle of the Z-domain so that they are no longer equally spaced. This is shown in FIG. 6. Equally spaced poles correspond to equally spaced multiple pass-bands in the frequency domain, while non-equally spaced poles correspond to non-equally spaced multiple pass bands in the frequency domain. This is shown in FIG. 4. It should be noted, of course, that the transfer function for each of the path filters can be implemented using digital logic.

A refinement to the N-path filter of FIG. 5 is the provision of “gain” to the charge of each “rotating” capacitor. This can be achieved using an operational amplifier as shown in FIG. 7. In FIG. 7, the charge on the “rotating” capacitor Cr1 is duplicated on the capacitor connected to the output of the operational amplifier. The resulting a coefficient in the transfer function becomes multiplied by a factor of 2. With this additional option, increased freedom becomes possible in the design of the filter pass-band characteristic. Of course, operational amplifiers can be coupled to all or some of the rotating capacitors as desired.

A person understanding this invention may now conceive of alternative structures and embodiments or variations of the above all of which are intended to fall within the scope of the invention as defined in the claims that follow.

Having thus described the invention, what is claimed as new and secured by Letters Patent is:

1. A multiple path filter for filtering electronic signals, the filter comprising:
a signal insertion block, said signal insertion block receiving an input signal and converting said signal into a plurality of interleaved signals;
a plurality of path filters, each path filter receiving one of said interleaved signals and having a path filter output signal;
a cross-coupling mechanism, said cross-coupling mechanism, when activated, couples at least one of said path filters with at least one other path filter;
an output block, said output block receiving a plurality of path filter output signals from said path filters in an interleaved manner, said output block converting said path filter output signals into an output signal of said multiple path filter;
wherein
for each of said path filters, said path filter output signal is responsive to at least one signal from at least one other path filter received by way of said cross-coupling mechanism.

2. A filter according to claim 1 wherein for each of said path filters, said path filter output signal is responsive to at least one path filter output signal from at least one other path filter.

3. A filter according to claim 1 wherein each path filter's z-domain transfer function is responsive to at least one signal from at least one other path filter.

4. A filter according to claim 3 wherein each path filter's z-domain transfer function is implemented using digital logic.

5. A filter according to claim 1 wherein said signal insertion block inserts a charge into a first memory capacitor of each path filter.

6. A filter according to claim 5 wherein said cross-coupling mechanism comprises a plurality of switches and capacitors, each switch being for coupling a capacitor to one of said path filters, at least one capacitor of said cross-coupling mechanism being coupleable to at least one path filter, a single path filter being active at any one time.

7. A filter according to claim 6 wherein each capacitor from said cross-coupling mechanism transfers charge between different path filters by sharing charge with memory capacitors of different path filters.

8. A filter according to claim 6 wherein at least one capacitor of said cross-coupling mechanism transfers charge between path filters by sharing of charge with a first memory capacitor of each path filter.

9. A multi-filter circuit having an output comprising:
signal insertion block for inserting a charge into said circuit;
a plurality of N filter subcircuits, each of said filter subcircuits being formed by an activation or deactivation of a signal transfer mechanism such that only one filter subcircuit is active at any time and such that every filter subcircuit provides a different signal path for said charge, each filter subcircuit being a discrete time function of said charge, said output, and at least one intermediate signal from another filter subcircuit, N being a natural number;
at least one clock generator for generating control signals which activate or deactivate said signal transfer mechanism;
an output block for transferring outputs of each of said plurality of filter subcircuits to said output of said multi-filter circuit.

10. A circuit according to claim 9 wherein said intermediate signal is from a valid output signal N−1 cycles from a current cycle.

11. A circuit according to claim 9 wherein said plurality of filter subcircuits comprises:
a plurality of memory capacitors, each memory capacitor being coupled to said signal insertion mechanism, each memory capacitor being designated for a specific filter subcircuit;
a plurality of rotating capacitors, each of said plurality of rotating capacitors being coupled to a plurality of switches, activation of selected switches coupling at least one of said rotating capacitors to a selected memory capacitor and thereby forming a filter subcircuit.

12. A circuit according to claim 11 further including at least one operational amplifier is coupled to a rotating capacitor.
